(19) United States
(12) Patent Application Publication
(10) Pub. No.: US 2025/0207331 A1
(43) Pub. Date: Jun. 26, 2025

(54) A METHOD FOR MANUFACTURING A VACUUM COATED PAPER

(71) Applicant: Stora Enso OYJ, Helsinki (FI)

(72) Inventors: Kaj Backfolk, Lappeenranta (FI); Isto Heiskanen, Imatra (FI); Cecilia Land Hensdal, Forshaga (SE)

(73) Assignee: Stora Enso OYJ, Helsinki (FI)

(21) Appl. No.: 18/851,730

(22) PCT Filed: Mar. 28, 2023
(86) PCT No.: PCT/IB2023/053053

§ 371 Date: Sep. 27, 2024

(30) Foreign Application Priority Data
Mar. 31, 2022 (SE) 2230100-6

(51) Int. Cl. D21H 19/08; C23C 14/20; D21H 19/54; D21H 19/56; D21H 19/82

(52) U.S. Cl. CPC D21H 19/08; C23C 14/20; D21H 19/54; D21H 19/56; D21H 19/82

(57) ABSTRACT

The present invention relates to a method for manufacturing a vacuum coated paper, said method comprising: a) providing a paper substrate, wherein said paper substrate comprises 0.3-60 kg/ton of a humectant, based on the total dry weight of the paper substrate, b) applying a precoat layer to the paper substrate, and c) applying a vacuum coating layer to the precoat layer to obtain a vacuum coated paper. The present invention further relates to a vacuum coated paper.

### TECHNICAL FIELD

The present disclosure relates to vacuum coated paper for use as barrier layers in paper or paperboard based packaging laminates. More specifically, the present disclosure relates to vacuum coated paper for paper or paperboard based packaging laminates having low oxygen transmission rate (OTR) and low water vapor transmission rate (WVTR).

### BACKGROUND

Coating of paper and paperboard with plastics is often employed to combine the mechanical properties of the paper or paperboard with the barrier and sealing properties of a plastic film. Paper or paperboard provided with even a relatively small amount of a suitable plastic material can provide the properties needed to make the paper or paperboard suitable for many demanding applications, for example as liquid or food packaging board. In liquid or food packaging board, polyolefin coatings are frequently used as liquid barrier layers, heat sealing layers and adhesives. However, the recycling of such polymer coated board is difficult since it is difficult to separate the polymers from the fibers.

Also, in many cases the water vapor barrier properties of the polymer coated paper or paperboard are still insufficient unless the coating layers are thick or combinations of different polymer coating layers are used. Therefore, in order to ensure high water vapor barrier properties, the polymer coated paper or paperboard is often combined with one or more layers of aluminum foil. However, the addition of polymer and aluminum foil add significant costs and the combination of polymer coating layers and aluminum foils makes recycling of the materials more difficult. Also, due to its high carbon footprint there is a wish to replace aluminum foils in paper and paperboard based packaging materials.

Aseptic packaging for long shelf-life products such as milk and juices are usually made from liquid or food packaging board comprising a multilayer paperboard based substrate, an outermost heat-sealable polyolefin (e.g. polyethylene, PE) layer and innermost layers of polyolefin and aluminum. The aluminum foil layer, needed to provide water vapor and oxygen barrier properties, is usually incorporated between layers of polyethylene to provide the following structure: PE/paperboard/PE/aluminum/PE.

In the prior art, attempts have been made to replace the aluminum foil with more environmentally friendly and/or easier to recycle solutions, but so far with no real success.

A solution presented in the prior art is to prepare a barrier layer by providing a high-density paper or compact paper substrate with a vacuum deposited organic or inorganic barrier coating layer. The vacuum deposited barrier coating layer may for example comprise or consist of AIOx, Al₂O₃ or SiOx. The vacuum coated barrier layer is then laminated to a paper or paperboard base layer to provide the base layer with improved barrier properties.

A problem with vacuum deposition techniques is that the paper substrate to be subjected to the vacuum deposition should have high smoothness and provide good adhesion to the vacuum deposited coating. For these reasons, it is common to use mineral or clay coated thin paper substrates, such as label paper, for vacuum deposition.

Another problem with the vacuum deposition techniques is that the coating process takes place under vacuum, which means that the substrate needs to be degassed. This means that the process adds costs, but the degassing also means that the paper substrate is dried to a very low moisture content. This drying and the subsequent remoisturizing to ambient moisture levels changes the mechanical properties of the substrate. The drying will not only negatively affect the curling and cracking tendency and post-convertability of the vacuum coated substrate, but there is also a significant risk of cracking of the thin and sensitive vacuum deposition layer due to hygroexpansion as the paper substrate is remoisturized.

One solution to solve the problems with hygroexpansion would be to increase filler content. Fillers may reduce costs and improve dimensional stability and optical properties of the substrate, but will impact barrier properties negatively. Fillers lead to increased thermal conductivity, which may further increase the risks for defects such as curl, electrostatic charging, and cracking of surface size or coating.

Thus, there remains a need for improved solutions to replace the combination of plastic films and aluminum foils in paper and paperboard based packaging materials, while maintaining acceptable liquid, water vapor, and oxygen barrier properties. At the same time, there is a need to replace the combination of plastic films and aluminum foils with alternatives that facilitate repulping and recycling of the used packaging materials.

### DESCRIPTION OF THE INVENTION

It is an object of the present disclosure to provide an alternative to the combination of plastic films and aluminum foils commonly used as barrier layers for providing water vapor barrier properties in packaging materials, such as liquid or food packaging board.

It is a further object of the present disclosure, to provide a barrier layer for a paper or paperboard based packaging laminate, such as a liquid or food packaging board, which provides good water vapor barrier properties even at higher relative humidity and temperature.

It is a further object of the present disclosure to provide a barrier layer, which has an oxygen transmission rate (OTR), measured according to the standard ASTM F1927-98 at 50% relative humidity and 23° C., of less than 10 cc/m²/24 h.

It is a further object of the present disclosure to provide a barrier layer, which has a water vapor transmission rate (WVTR), measured according to the standard ASTM F1249-90 at 50% relative humidity and 23° C., of less than 10 g/m²/24 h.

It is a further object of the present disclosure to provide a barrier layer for a paper or paperboard based packaging laminate, such as a liquid or food packaging board, which barrier layer facilitates re-pulping of the packaging laminate as compared to packaging laminates using conventional combinations of plastic films and aluminum foils.

The above-mentioned objects, as well as other objects as will be realized by the skilled person in the light of the present disclosure, are achieved by the various aspects of the present disclosure.

The present invention is based on the understanding that very thin coating layers, typically having a thickness in the range of 20-600 nm, and more preferably in the range of 50-250 nm, formed by vacuum deposition processes, such as physical vapor deposition (PVD) or chemical vapor deposition (CVD), can when applied to a suitable paper substrate provide good oxygen and water vapor barrier properties, comparable to the barrier properties of thicker aluminum foils. As the thickness of the vacuum deposited coatings is typically at least an order of magnitude lower than the thickness of conventional foils, the metal content of the products can be dramatically reduced.

However, vacuum deposition coating performed directly on the paper substrate to be coated, so called direct vacuum coating, or direct metallization, has been found to be problematic. More specifically, degassing in connection with the vacuum treatment means that the paper substrate is dried to a very low moisture content. This drying and the subsequent remoisturizing to ambient moisture levels changes the mechanical properties of the paper substrate. The drying will not only negatively affect the cracking tendency and post-convertability of the paper substrate, but there is also a significant risk of cracking of the thin and sensitive vacuum coating layer as the substrate is remoisturized.

The present invention is based on the realization that these problems can be overcome by providing the paper substrate with an effective amount of a humectant. A humectant provided in the bulk or on the surface of the paper substrate has been found to ameliorate the negative effects of overdrying during vacuum treatment.

Low moisture content obtained after vacuum coating might also cause electrostatic charges and risks for curl and problems with runnability. It is believed that the humectant may improve electrostatic properties of the substrate, e.g. by less tribocharging, reducing the need to re-moisturize the dried substrate.

A risk with adding humectants in a barrier layer is that they may be expected to cause pinholes or weak boundary layers. They could also affect the crystallization of polymers, which could lead to problems when used in barrier layers. However, the present inventors have surprisingly found that vacuum coated paper prepared with a substrate comprising an effective amount of a humectant also exhibits excellent oxygen and water vapor barrier properties.

According to a first aspect illustrated herein, there is provided a method for manufacturing a vacuum coated paper, said method comprising:
a) providing a paper substrate, wherein said paper substrate comprises 0.3-60 kg/ton of a humectant, based on the total dry weight of the paper substrate,
b) applying a precoat layer to the paper substrate, and
c) applying a vacuum coating layer to the precoat layer to obtain a vacuum coated paper.

The method uses a paper substrate comprising 0.3-60 kg/ton of a humectant, based on the total dry weight of the paper substrate, which acts to protect the paper substrate from overdrying during the vacuum treatment.

A humectant is a hygroscopic substance used to keep products, materials or formulations moist. Humectants are used in many products, including food, cosmetics, medicines and pesticides. Humectants are also sometimes used as a component of antistatic coatings for plastic materials.

A humectant attracts and retains the moisture in the air nearby via absorption, drawing the water into or beneath the surface of the product, material or formulation. The humectant also helps to retain water more efficiently when a wet composition is subjected to drying. Common examples of humectant substances, i.e. humectants, include but are not limited to low molecular weight polyols, sugar alcohols and metal salts. Particularly preferred are humectants that are listed as safe for direct or indirect food contact.

The paper substrate may be any paper substrate, but the method is especially useful for lower grammage substrates, e.g. thin substrates, since such substrates are more easily overdried. In some embodiments, the paper substrate has a grammage in the range of 20-150 g/m², preferably in the range of 20-100 g/m², and more preferably in the range of 30-80 g/m².

The paper substrate to be subjected to vacuum coating may often comprise a mineral filler. In some embodiments, the paper substrate comprises a mineral filler in an amount of 1-30 wt %, based on the total dry weight of the paper substrate.

In some embodiments, the paper substrate is formed of a cellulose pulp composition having a Schopper-Riegler (SR) number below 35, and preferably below 30, as determined by standard ISO 5267-1.

In some embodiments, the paper substrate comprises less than 20 wt % of highly refined cellulose (HRC) or microfibrillated cellulose (MFC) having a Schopper-Riegler (SR) number above 80 as determined by standard ISO 5267-1, based on dry weight.

The paper substrate itself, before precoating and vacuum coating, will typically have a high permeability for gases, such as oxygen, air and carbon dioxide. In some embodiments, the paper substrate has a Gurley Hill value below 5000 s/100 ml, preferably below 2000 s/100 ml, and more preferably below 1000 s/100 ml, as measured according to standard ISO 5636-5.

The paper substrate itself, before precoating and vacuum coating, will typically have a high permeability for water vapor. In some embodiments, the paper substrate has a water vapor transmission rate (WVTR), measured according to the standard ASTM F1249-90 at 50% relative humidity and 23° C., of above 200 g/m²/24 h.

The paper substrate itself, before precoating and vacuum coating, will typically have low or no resistance to oil and grease penetration. In some embodiments, the paper substrate itself, before precoating and vacuum coating, has a KIT value below 5, preferably below 3, and more preferably below 1, as measured according to standard TAPPI T559.

The opacity of the paper substrate is typically above 80%, and preferably above 85%, as determined according to ISO 2471.

The paper substrate may also be surface sized. In some embodiments, the paper substrate is surface sized on one or both sides with a surface sizing composition, preferably comprising starch or a starch derivative, or a combination of starch or a starch derivative and microfibrillated cellulose.

In some embodiments, the surface sizing composition comprises a starch which has not been chemically modified.

In some embodiments, the grammage of the surface sizing composition is 0.2-10 g/m², preferably 0.4-8 g/m², and more preferably 0.8-5 g/m² per side, based on dry weight.

In some embodiments, the paper substrate comprises 0.5-50 kg/ton, preferably 1-40 kg/ton, and more preferably 5-30 kg/ton, of the humectant, based on the total dry weight of the paper substrate.

In some embodiments, the humectant is selected from the group consisting of low molecular weight polyols, sugar alcohols, metal salts, and combinations thereof.

In some embodiments, the humectant is a sugar alcohol, preferably sorbitol.

In some embodiments, the humectant is a metal salt, preferably a divalent or trivalent metal salt. In some embodiments, the humectant is a metal salt selected from the group consisting of calcium chloride, calcium acetate, magnesium acetate, and calcium magnesium acetate. In some embodiments, the humectant is calcium chloride. In some embodiments, the humectant is a metal salt selected from the group consisting of calcium acetate, magnesium acetate, and calcium magnesium acetate.

In some embodiments, the humectant is present in the bulk of the paper substrate, or at the surface of the paper substrate, or both.

In some embodiments, the humectant has been added to the furnish during the papermaking process, such that the humectant is dispersed within the bulk of the paper substrate.

In some embodiments, the humectant has been added to the surface of the paper substrate, after or during the forming of the substrate, e.g. in the form of a coating, as part of a surface sizing or surface treatment composition applied to the substrate. Thus, in some embodiments, the humectant is present at the surface of the paper substrate, preferably as part of a surface sizing composition. In some embodiments, the paper substrate comprises the humectant at the surface of the paper substrate facing the precoat layer. In some embodiments, the paper substrate comprises the humectant in a coating, surface sizing, or surface treatment composition at the surface of the paper substrate facing the precoat layer. In some embodiments, the paper substrate comprises the humectant in a coating, surface sizing, or surface treatment composition further comprising starch, preferably a starch which has not been chemically modified, at the surface of the paper substrate facing the precoat layer.

In some embodiments, the paper substrate comprises the humectant in a coating, surface sizing, or surface treatment composition, preferably further comprising starch, at the surface of the paper substrate on both sides of the paper substrate. The coating, surface sizing, or surface treatment composition, comprising the humectant may improve printability of the surface not facing the precoat layer, particularly when the humectant is a metal salt.

The humectant may also be present both in the bulk and at the surface of the paper substrate. A humectant may for example have been added both to the furnish and as a coating, surface sizing, or surface treatment composition, or a humectant added in a coating, surface sizing, or surface treatment composition may have also penetrated into the bulk of the paper substrate.

To the optionally surface sized paper substrate a precoat layer is applied. The precoat layer renders the surface of the paper substrate smoother and less porous before the vacuum coating layer is applied. The precoat layer may also improve the adhesion of the vacuum coating layer. Preferably, the precoat layer may also improve the gas, water vapor, and/or liquid barrier properties of the coated substrate.

The precoat layer will also provide a barrier against migration of low molecular weight substances from the paper substrate. This may be especially useful in the method according to the present disclosure, since some humectants may be volatile or prone to migration and hence cause deposits in the vacuum coating machine. Some humectants may reduce adhesion to the vacuum coating layer, and some humectants may also be corrosive. Without being bound to any scientific theory, it is believed that a polymeric precoat layer can provide not only good adhesion to the vacuum coating layer, but also good barrier for migration of the humectant.

The precoat layer may be applied by any suitable method known in the art. The precoat layer may for example be applied as a solution or dispersion in an aqueous or organic solvent carrier using liquid coating methods known in the art, in melt form using extrusion coating, or in the form of a solid film by lamination.

The precoat layer is preferably formed by means of a liquid film coating process, i.e. in the form of a solution or dispersion which, on application, is spread out to a thin, uniform layer on the substrate and thereafter dried. The liquid phase of the solution or dispersion is preferably water or an aqueous solution, but organic solvents or mixtures of water or aqueous solutions and organic solvents may also be used. The one or more polymers may be present in the solution or dispersion in dissolved form or in the form of polymer particles, such as a latex. The precoat layer can be applied by contact or non-contact coating methods. Examples of useful coating methods include, but are not limited to rod coating, curtain coating, film press coating, cast coating, transfer coating, size press coating, flexographic coating, gate roll coating, twin roll HSM coating, blade coating, such as short dwell time blade coating, jet applicator coating, spray coating, gravure coating or reverse gravure coating.

To minimize the risk of pinholes in the precoat layer, the precoat layer may preferably be applied in at least two different coating steps with drying of the coated film between the steps. The air content of the coating solution or dispersion is preferably less than 1%.

In some embodiments, at least one precoat layer is applied in the form of a foam. Foam coating is advantageous as it allows for film forming at higher solids content and lower water content compared to a non-foamed coating. The lower water content of a foam coating also reduces the problems with rewetting of the paper substrate. The foam may be formed using a polymeric or non-polymeric foaming agent. Examples of polymeric foaming agents include PVOH, hydrophobically modified starch, and hydrophobically modified ethyl hydroxyethyl cellulose.

Typically, the precoat layer will comprise one or more polymers. The precoat layer may be comprised entirely of the one or more polymers, or it may also further comprise other additives for facilitating the coating process or improving the properties of the precoat layer.

In some embodiments, the precoat layer comprises at least 50 wt % of a polymer or mixture of polymers based on dry weight.

In some embodiments, the precoat layer comprises a polymer selected from the group consisting of a polyvinyl alcohol (PVOH), a polyurethane, a polysaccharide, and a combination thereof, preferably PVOH. The polysaccharide may be a natural polysaccharide or a chemically modified polysaccharide, for example a chemically modified cellulose, such as a carboxymethyl cellulose (CMC).

In some embodiments, the precoat layer comprises at least 50 wt % of a water-soluble polymer or mixture of water-soluble polymers based on dry weight. The water-soluble polymer of the precoat layer is soluble in cold water or soluble in hot water, e.g. at a temperature below 100° C. or even above 100° C., for a given period of time. The water-soluble polymer in addition to acting as an adhesive for the vacuum coating layer, also facilitates separation of the vacuum coating layer and optional additional plastic layers applied on top of the precoat layer or vacuum coating layer during repulping. In some embodiments, the water-soluble polymer is selected from the group consisting of a polyvinyl alcohol (PVOH), a chemically modified cellulose, a starch, an alginate, and a hemicellulose. In some embodiments, the water-soluble polymer is selected from the group consisting of a polyvinyl alcohol (PVOH), a carboxymethyl cellulose (CMC), a starch, an alginate, and a hemicellulose, preferably a PVOH.

In some embodiments, the precoat layer comprises at least 50 wt % of a PVOH, preferably at least 70 wt % of a PVOH, based on the total dry weight of the precoat layer.

In some embodiments, the PVOH has a degree of hydrolysis in the range of 80-99 mol %, preferably in the range of 85-99 mol %. In some embodiments, the PVOH has an ash content of less than 4 wt %, preferably less than 3 wt %, and more preferably less than 2.5 wt %. In some embodiments, the PVOH is a washed PVOH.

In some embodiments, the precoat layer also comprises a humectant. When the precoat layer comprises more than one layer, the humectant may preferably be comprised in one of the layers. In some embodiments, the precoat layer also comprises 1-30 wt %, preferably 1-20 wt %, and more preferably 1-10 wt %, of humectant based on the dry weight of the precoat layer. The humectant in the precoat layer may be the same as in the paper substrate, or different.

In some embodiments, the precoat layer further comprises a crosslinking agent capable of crosslinking the water-soluble polymer. The crosslinking agent may advantageously be applied together with the water-soluble polymer, and then activated, e.g. by heat or radiation, when the precoat layer is in contact with the vacuum coating layer. Crosslinking improves the water vapor barrier properties of the precoat layer. Suitable crosslinking agents include, but are not limited to polyfunctional organic acids or aldehydes, such as citric acid, glyoxal, and glutaraldehyde. In some embodiments, the crosslinking agent is an organic acid, and more preferably citric acid. The concentration of the crosslinking agent may for example be 1-20 wt %, preferably 1-15 wt %, based on the dry weight of the precoat layer.

In some embodiments, the precoat layer comprises PVOH and citric acid. Crosslinking of the PVOH with citric acid improves the water vapor barrier properties of the precoat layer. Additionally, the crosslinking of the PVOH with citric acid in contact with the vacuum coating layer has been found to further improve adhesion of the vacuum coating layer and the overall water vapor barrier properties of the vacuum coated paper.

In some embodiments, the precoat layer comprises one or more additional polymer(s) in a total amount of 1-50 wt % based on dry weight. The additional polymer(s) may act to crosslink and/or further improve adhesion to the vacuum coating layer. Suitable additional polymer(s) include, but are not limited to polyvinyl pyrrolidone, polyvinyl amide, polyvinyl ethylene imine, polyacrylamide, cationic polyacrylamide, polyurethane, and derivatives thereof. Other suitable additional polymer(s) include latexes, such as styrene acrylate latex (SA latex), styrene butadiene latex (SB latex), polyvinyl acetate (PVAc), styrene butadiene acrylonitrile (SBN), polyvinylidene dichloride (PVDC), and hybrid-polymer emulsions such as grafted starch.

In some embodiments, the grammage of the precoat layer is in the range of 1-20 g/m², preferably in the range of 2-15 g/m², more preferably in the range of 3-12 g/m², based on dry weight. Without being bound to any theory, it is believed that a grammage according to these ranges may provide not only good adhesion to vacuum coating layer, but also good barrier for migration of humectants from the paper substrate during the vacuum coating process.

After the precoat layer has been applied, a vacuum coating layer is applied to the precoat layer to obtain a vacuum coated paper. The humectant acts to protect the paper substrate from becoming excessively dried out during the vacuum treatment.

Vacuum coating refers to a family of processes used to deposit layers of metals, metal oxides and other inorganic and organic compositions, typically atom-by-atom or molecule-by-molecule, on a solid surface. Multiple layers of the same or different materials can be combined. The process can be further specified based on the vapor source; physical vapor deposition (PVD) uses a liquid or solid source and chemical vapor deposition (CVD) uses a chemical vapor.

Vacuum coating typically results in very thin coatings. In some embodiments, the vacuum coating layer has a thickness in the range of 10-600 nm, preferably in the range of 10-250 nm, and more preferably in the range of 50-250 nm. This may be compared to conventional aluminum foils used in packaging laminates, which foils typically have thickness in the range of about 3-12 μm.

In some embodiments, the vacuum coating layer is applied to the precoat layer by physical vapor deposition (PVD) or chemical vapor deposition (CVD).

The vacuum coating layer may be inorganic or organic. In some embodiments, the vacuum coating layer is an inorganic vacuum coated layer, such as a metal, metal oxide, or ceramic vacuum coating layer.

In some embodiments, the vacuum coating layer comprises a metal or metal oxide selected from the group consisting of aluminum, magnesium, silicon, copper, aluminum oxides, magnesium oxides, silicon oxides, and combinations thereof, preferably an aluminum oxide.

One preferred type of vacuum coating, often used for its barrier properties, in particular water vapor barrier properties, is an aluminum metal physical vapor deposition (PVD) coating. Such a coating, substantially consisting of aluminum metal, may typically have a thickness of from 50 to 250 nm, although a thickness even lower than 50 nm may also be useful, and even preferred in some embodiments. The thickness of the vacuum coating layer corresponds to less than 1% of the aluminum metal material typically present in an aluminum foil of conventional thickness for packaging, i.e. 6.3 μm. Thus, in some embodiments, the vacuum coating layer comprises aluminum.

The thickness of the vacuum coating layer may also be characterized by the optical density of the layer. In some embodiments the vacuum coating layer has an optical density above 1.8, preferably above 2.0, above 2.5, above 2.7, or above 3.0.

Aluminum oxide vacuum coating layers also known as AlOx coatings can provide similar barrier properties as aluminum metal coatings, but have the added advantage of thin AIOx coatings being transparent to visible light.

In some embodiments, the vacuum coating layer is an organic vacuum coated layer. In some embodiments, the vacuum coating layer comprises carbon. The organic vacuum coating may for example be a vacuum coated carbon layer, such as a diamond-like carbon (DLC) layer formed from carbon or organic compounds.

In some embodiments, the vacuum coating layer has a thickness in the range of 10-600 nm, preferably in the range of 10-250 nm, and more preferably in the range of 50-250 nm.

In some more specific embodiments, the humectant is a metal salt and the precoat layer comprises at least 50 wt % of a PVOH based on the total dry weight of the precoat layer.

In some more specific embodiments, the humectant is a metal salt, the precoat layer comprises at least 50 wt % of a PVOH based on the total dry weight of the precoat layer, and the vacuum coating layer comprises a metal or metal oxide.

In some more specific embodiments, the humectant is a calcium salt, the precoat layer comprises at least 50 wt % of a PVOH based on the total dry weight of the precoat layer, and the vacuum coating layer comprises aluminum.

In some more specific embodiments, the humectant is a metal salt and the precoat layer comprises at least 50 wt % of a CMC based on the total dry weight of the precoat layer.

In some more specific embodiments, the humectant is a metal salt, the precoat layer comprises at least 50 wt % of a CMC based on the total dry weight of the precoat layer, and the vacuum coating layer comprises a metal or metal oxide.

In some more specific embodiments, the humectant is a calcium salt, the precoat layer comprises at least 50 wt % of a CMC based on the total dry weight of the precoat layer, and the vacuum coating layer comprises aluminum.

In some of the more specific embodiments, the paper substrate comprises the humectant at the surface of the paper substrate facing the precoat layer. In some embodiments, the paper substrate comprises the humectant in a coating, surface sizing, or surface treatment composition at the surface of the paper substrate facing the precoat layer. In some embodiments, the paper substrate comprises the humectant in a coating, surface sizing, or surface treatment composition further comprising starch, preferably a starch which has not been chemically modified, at the surface of the paper substrate facing the precoat layer.

In some of the more specific embodiments, the precoat layer further comprises a crosslinking agent capable of crosslinking the PVOH or CMC. The crosslinking agent may advantageously be applied together with the PVOH or CMC, and then activated, e.g. by heat or radiation, when the precoat layer is in contact with the vacuum coating layer. Crosslinking improves the water vapor barrier properties of the precoat layer. Suitable crosslinking agents include, but are not limited to polyfunctional organic acids or aldehydes, such as citric acid, glyoxal, and glutaraldehyde. In some embodiments, the crosslinking agent is an organic acid, and more preferably citric acid. The concentration of the crosslinking agent may for example be 1-20 wt %, preferably 1-15 wt %, based on the dry weight of the precoat layer. In some embodiments, the precoat layer comprises the PVOH or CMC and an organic acid, and more preferably citric acid.

The coating of the paper substrate with the precoat layer and vacuum coating layer significantly improves the oxygen and water vapor barrier properties of the vacuum coated paper as compared to the uncoated paper substrate.

In some embodiments, the obtained vacuum coated paper has an oxygen transmission rate (OTR), measured according to the standard ASTM F1927-98 at 50% relative humidity and 23° C., of less than 10 cc/m²/24 h, preferably less than 5 cc/m²/24 h, and more preferably less than 1 cc/m²/24 h.

In some embodiments, the obtained vacuum coated paper has a water vapor transmission rate (WVTR), measured according to the standard ASTM F1249-90 at 50% relative humidity and 23° C., of less than 10 g/m²/24 h, preferably less than 5 g/m²/24 h, and more preferably less than 1 g/m²/24 h.

In addition to providing good oxygen and water vapor barrier properties, the inventive vacuum coated paper may also form a good barrier for other gases, as well as aromas and odors.

The obtained vacuum coated paper typically has significantly better oil and grease barrier properties as compared to the paper substrate itself. In some embodiments, the obtained vacuum coated paper has a KIT value of at least 8, preferably at least 10, and more preferably at least 12, as measured according to standard TAPPI T559.

The method according to the first aspect described herein allows for the preparation of improved vacuum coated papers. The paper comprises 0.3-60 kg/ton of a humectant, based on the total dry weight of the paper substrate which protects the paper substrate from excessive drying. Excessive drying may for example be caused by subjecting the vacuum coated paper to high temperatures, such temperatures exceeding 100° C., for example during hot lamination, extrusion coating or heat sealing processes. The drying will not only negatively affect the curling and cracking tendency and convertability of the vacuum coated paper, but there is also a significant risk of cracking of the thin and sensitive vacuum deposition layer due to hygroexpansion as the paper substrate is subsequently remoisturized.

Thus, according to a second aspect illustrated herein, there is provided a vacuum coated paper comprising:
a paper substrate,
a precoat layer, and
a vacuum coating layer,
wherein the precoat layer is arranged between and in contact with the paper substrate and the vacuum coating layer, and
wherein said paper substrate comprises 0.3-60 kg/ton of a humectant, based on the total dry weight of the paper substrate.

In some embodiments, the paper substrate is surface sized, on one or both sides thereof with a surface sizing composition, preferably comprising starch or a starch derivative, or a combination of starch or a starch derivative and microfibrillated cellulose.

In some embodiments, the surface sizing composition comprises a starch which has not been chemically modified.

In some embodiments, the grammage of the surface sizing composition is 0.2-10 g/m², preferably 0.4-8 g/m², and more preferably 0.8-5 g/m² per side.

In some embodiments, the humectant is selected from the group consisting of low molecular weight polyols, sugar alcohols, metal salts, and combinations thereof.

In some embodiments, the humectant is present in the bulk of the paper substrate, or at the surface of the paper substrate, or both.

In some embodiments, the humectant is present at the surface of the paper substrate, preferably as part of a surface sizing composition.

The vacuum coated paper according to the second aspect described herein, and the components thereof, including the paper substrate, the precoat layer, and the vacuum coating layer, may be further defined as described with reference to the first aspect.

In some more specific embodiments, the humectant is a metal salt and the precoat layer comprises at least 50 wt % of a PVOH based on the total dry weight of the precoat layer.

In some more specific embodiments, the humectant is a metal salt, the precoat layer comprises at least 50 wt % of a PVOH based on the total dry weight of the precoat layer, and the vacuum coating layer comprises a metal or metal oxide.

In some more specific embodiments, the humectant is a calcium salt, the precoat layer comprises at least 50 wt % of a PVOH based on the total dry weight of the precoat layer, and the vacuum coating layer comprises aluminum.

In some more specific embodiments, the humectant is a metal salt and the precoat layer comprises at least 50 wt % of a CMC based on the total dry weight of the precoat layer.

In some more specific embodiments, the humectant is a metal salt, the precoat layer comprises at least 50 wt % of a CMC based on the total dry weight of the precoat layer, and the vacuum coating layer comprises a metal or metal oxide.

In some more specific embodiments, the humectant is a calcium salt, the precoat layer comprises at least 50 wt % of a CMC based on the total dry weight of the precoat layer, and the vacuum coating layer comprises aluminum.

In some of the more specific embodiments, the paper substrate comprises the humectant at the surface of the paper substrate facing the precoat layer. In some embodiments, the paper substrate comprises the humectant in a coating, surface sizing, or surface treatment composition at the surface of the paper substrate facing the precoat layer. In some embodiments, the paper substrate comprises the humectant in a coating, surface sizing, or surface treatment composition further comprising starch, preferably a starch which has not been chemically modified, at the surface of the paper substrate facing the precoat layer.

In some of the more specific embodiments, the precoat layer is crosslinked by a crosslinking agent capable of crosslinking the PVOH or CMC. The crosslinking agent may advantageously have been applied together with the PVOH or CMC, and then activated, e.g. by heat or radiation, when the precoat layer is in contact with the vacuum coating layer. Crosslinking improves the water vapor barrier properties of the precoat layer. Suitable crosslinking agents include, but are not limited to polyfunctional organic acids or aldehydes, such as citric acid, glyoxal, and glutaraldehyde. In some embodiments, the crosslinking agent is an organic acid, and more preferably citric acid. The concentration of the crosslinking agent may for example be 1-20 wt %, preferably 1-15 wt %, based on the dry weight of the precoat layer. In some embodiments, the precoat layer comprises the PVOH or CMC crosslinked by an organic acid, more preferably by citric acid.

According to a third aspect illustrated herein, there is provided a method for manufacturing a paper or paperboard based packaging laminate, said method comprising:
i) providing a paper or paperboard base layer, and
ii) laminating a vacuum coated paper according to the second aspect, or manufactured according to the first aspect, to the paper or paperboard base layer to obtain a paper or paperboard based packaging laminate.

Paper generally refers to a material manufactured in thin sheets from the pulp of wood or other fibrous substances comprising cellulose fibers, used for writing, drawing, or printing on, or as packaging material.

Paperboard generally refers to strong, thick paper or cardboard comprising cellulose fibers used for boxes and other types of packaging. Paperboard can either be bleached or unbleached, coated or uncoated, and produced in a variety of thicknesses, depending on the end use requirements. Paperboard may be a single ply material, or a multiply material comprised of two or more plies. A common type of multiply paperboard is comprised of a lower density mid-ply (also sometimes referred to as “bulk ply”) sandwiched between two higher density outer plies. The lower density mid-ply may typically have a density below 750 kg/m³, preferably below 700, below 650, below 600, below 550, below 500, below 450, below 400 or below 350 kg/m³. The higher density outer plies typically have a density at least 100 kg/m³ higher than the mid-ply, preferably at least 200 kg/m³ higher than the mid-ply.

A paper or paperboard based packaging laminate is a packaging material formed mainly from paperboard. The paper or paperboard base layer can be made from pulp, including pulp from virgin fiber, e.g. mechanical, chemical and/or thermomechanical pulps. It can also be made from broke or recycled paper. In addition to the paper or paperboard, the paper or paperboard based packaging laminate may comprise additional layers or coatings designed to improve the performance and/or appearance of the packaging laminate.

The paper or paperboard based packaging laminate typically has a first outermost surface intended to serve as the outside surface, or print side, and a second outermost surface intended to serve as the inside surface of a packaging container. The side of the paper or paperboard base layer comprising the inventive vacuum coated paper is preferably intended to serve as the inside surface of a packaging container.

In some embodiments, the paper or paperboard base layer has a grammage of at least 100 g/m². In some embodiments, the paper or paperboard base layer has a grammage of at least 150 g/m², 200 g/m², 250 g/m², 300 g/m², 350 g/m², or 400 g/m². The grammage of the paper or paperboard base layer is preferably below 1000 g/m², 800 g/m², or 600 g/m². Unless otherwise stated, the grammage is determined according to the standard ISO 536.

In some embodiments, the paper or paperboard base layer has a density below 700 kg/m³, preferably below 600 kg/m³. Unless otherwise stated, the density is determined according to the standard ISO 534.

The paper or paperboard base layer may be a single ply paperboard or a multiply paperboard. In some embodiments, the paper or paperboard base layer is a multiply paperboard. In some embodiments the paper or paperboard base layer is a multiply paperboard comprised of two or more plies. In some embodiments the paper or paperboard base layer is a multiply paperboard comprised of three or more plies. In some embodiments the paper or paperboard base layer is a multiply paperboard comprised of a lower density mid-ply sandwiched between two higher density outer plies.

In some embodiments, the paper or paperboard base layer is a foam formed paperboard. In some embodiments wherein the paper or paperboard base layer is a multiply paperboard, at least one of the plies, preferably a mid-ply, is foam formed.

According to a fourth aspect illustrated herein, there is provided a paper or paperboard based packaging laminate obtained by a method according to the third aspect.

The paper or paperboard based packaging laminate can provide an alternative to conventional materials using aluminum foil layers, which can more readily be repulped and recycled. In some embodiments, the paper or paperboard based packaging laminate has a reject rate according to PTS RH 021/97 of less than 30%, preferably less than 20%, more preferably less than 10%.

The paper or paperboard based packaging laminate may further be provided with an outermost polymer layer on one side or on both sides. The outermost polymer layers preferably provide liquid barrier properties and mechanical protection for the paper or paperboard based packaging laminate surface. The outermost polymer layer is preferably also heat-sealable.

In some embodiments, the paper or paperboard based packaging laminate comprises a first outermost polymer layer, preferably a polyethylene layer, arranged on the paper or paperboard substrate.

In some embodiments, the paper or paperboard based packaging laminate further comprises a second outermost polymer layer, preferably a polyethylene layer, arranged on the vacuum coating layer.

The outermost polymer layers may of course interfere with repulpability but may still be required or desired in some applications. The additional polymer layers may for example be applied by extrusion coating, film lamination or dispersion coating.

The outermost polymer layers may comprise any of the thermoplastic polymers commonly used in protective and/or heat-sealable layers in paper or paperboard based packaging laminates in general or polymers used in liquid or food packaging board in particular. Examples include polyethylene (PE), polyethylene terephthalate (PET), polyethylene furanoate (PEF), polypropylene (PP), polyhydroxyalkanoates (PHA), polylactic acid (PLA), polyglycolic acid (PGA), starch and cellulose. Polyethylenes, especially low density polyethylene (LDPE) and high density polyethylene (HDPE), are the most common and versatile polymers used in liquid or food packaging board. The polymers used are preferably manufactured from renewable materials.

Thermoplastic polymers are useful since they can be conveniently processed by extrusion coating techniques to form very thin and homogenous films with good liquid barrier properties. In some embodiments, the additional polymer layer comprises polypropylene or polyethylene. In preferred embodiments, the outermost polymer layers comprise polyethylene, more preferably LDPE or HDPE.

In some embodiments, the outermost polymer layers are formed by extrusion coating of the polymer onto a surface of the paper or paperboard substrate or laminate. Extrusion coating is a process by which a molten plastic material is applied to a substrate to form a very thin, smooth and uniform layer. The coating can be formed by the extruded plastic itself, or the molten plastic can be used as an adhesive to laminate a solid plastic film onto the substrate. Common plastic resins used in extrusion coating include polyethylene (PE), polypropylene (PP), and polyethylene terephthalate (PET).

The basis weight of each of the outermost polymer layers is preferably less than 50 g/m². In order to achieve a continuous and substantially defect free film, a basis weight of the outermost polymer layer of at least 8 g/m², preferably at least 12 g/m² is typically required. In some embodiments, the basis weight of the outermost polymer layer is in the range of 8-50 g/m², preferably in the range of 12-50 g/m².

Generally, while the products, polymers, materials, layers and processes are described in terms of “comprising” various components or steps, the products, polymers, materials, layers and processes can also “consist essentially of” or “consist of” the various components and steps.

While the invention has been described with reference to various exemplary embodiments, it will be understood by those skilled in the art that various changes can be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

### EXAMPLES

### Example 1 (Comparative)

A 1-side mineral coated 44 gsm flexible packaging paper was used as the paper substrate. The paper substrate had an ash content of 7 wt % and a fiber mix comprised of 30% mechanical and 70% chemical kraft pulp. Details of the paper substrate are set out in Table I.

The paper was supercalendered and the mineral coated side of the paper substrate was then precoated offline with a PVOH solution with a lab coater as detailed in Table II and dried. The dry PVOH coated surface was then vacuum coated with aluminum metal in a commercial reel-to-reel vacuum deposition equipment to a coat weight corresponding to an optical density of 3.5 and 2.5 as detailed in Tables III and IV, respectively.

The oxygen transmission rate (OTR) and water vapor transmission rate (WVTR) of the paper substrate itself were too high to be measured, indicating poor barrier properties.

After the PVOH precoating, the OTR was reduced whereas the WVTR remained at a high level. After vacuum coating, the OTR increased whereas WVTR was reduced.

### Example 2 (Comparative)

An uncoated 65 gsm paper having a fiber mix comprised of 20% chemical pulp and 80% mechanical pulp (TMP) and containing no filler was used as the paper substrate. Details of the paper substrate are set out in Table I.

The paper was soft calendered and sheets of the paper substrate were then precoated offline with a PVOH solution with a lab coater as detailed in Table II and dried. The dry PVOH coated surface was then vacuum coated with aluminum as described in Example 1 to a coat weight corresponding to an optical density of 3.5 as detailed in Table III.

The oxygen transmission rate (OTR) and water vapor transmission rate (WVTR) of the paper substrate itself were too high to be measured, indicating poor barrier properties. The oxygen transmission rate (OTR) and water vapor transmission rate (WVTR) of the precoated substrate and of the vacuum coated paper were also too high to be measured.

### Example 3 (Comparative)

An uncoated 45 gsm paper having a fiber mix comprised of 20% chemical pulp and 80% mechanical pulp (TMP) and containing no filler was used as the paper substrate. Details of the paper substrate are set out in Table I.

The paper was soft calendered and sheets of the paper substrate were then precoated offline with a PVOH solution with a lab coater as detailed in Table II and dried. The dry PVOH coated surface was then vacuum coated with aluminum as described in Example 1 to a coat weight corresponding to an optical density of 3.5 as detailed in Table III.

The oxygen transmission rate (OTR) and water vapor transmission rate (WVTR) of the paper substrate itself were too high to be measured.

After the PVOH precoating, the OTR and the WVTR remained at a high level. However, after the vacuum coating, the WVTR was reduced, whereas the OTR remained at a high level.

### Example 4

A surface sized wood free 90 gsm paper comprising 30 wt % softwood, 40 wt % hardwood and 30 wt % broke and with 20% ash content was used as the paper substrate. The paper was surface sized with native starch and calcium chloride to a coat weight of ca 2-3 gsm per side. The surface size contained ca 20 kg calcium chloride per ton of paper, based on dry weight. The paper substrate had an opacity of 90-91% as determined according to ISO 2471. Details of the paper substrate are set out in Table I.

The paper was soft calendered and sheets of the paper substrate were then precoated offline with a PVOH solution with a lab coater as detailed in Table II and dried. The dry PVOH coated surface was then vacuum coated with aluminum as described in Example 1, to a coat weight corresponding to an optical density of 3.5 and 2.5 as detailed in Tables Ill and IV, respectively.

The oxygen transmission rate (OTR) and water vapor transmission rate (WVTR) of the paper substrate itself were too high to be measured, indicating poor barrier properties.

After the PVOH precoating, a clear improvement in barrier properties was detected. After the vacuum coating both OTR and WVTR properties were reduced to low levels, indicating good oxygen and water vapor barrier properties.

The vacuum coated paper had a reject rate according to PTS RH 021/97 of 0.6%.

TABLE I
Paper substrates used in the experiments

| Trial point | 1 | 2 | 3 | 4 |
|---|---|---|---|---|
| Grammage g/m² | 44.3 | 64.5 | 44.3 | 100.3 |
| Thickness, μm | 45 | 112 | 57 | 102 |
| Density, kg/m3 | 987 | 577 | 773 | 983 |
| Tensile strength, | 3.36 | 5.03 | 3.19 | 5.44 |
| kN/m, MD | | | | |
| Tensile strength, | 0.89 | 1.1 | 0.82 | 2.72 |
| kN/m, CD | | | | |
| Tensile stiffness, | 436.6 | 635.1 | 416.2 | 695.1 |
| kN/m, MD | | | | |
| Tensile stiffness, | 123.3 | 115.3 | 82 | 314.5 |
| kN/m, CD | | | | |
| Stretch at break, | 1.3 | 1.24 | 1.07 | 1.67 |
| %, MD | | | | |
| Stretch at break, | 2.37 | 2.23 | 2.34 | 4.88 |
| %, CD | | | | |
| Surface smoothness, PPS | 1.27 | 5.23 | 2.71 | 3.01 |
| 1.0 MPa, μm, TS | | | | |
| Surface smoothness, PPS | 1.94 | 5.35 | 2.91 | 3.07 |
| 1.0 MPa, μm, BS | | | | |
| Roughness Bendtsen, | 22 | 225 | 56 | 34 |
| ml/min, TS | | | | |
| Roughness Bendtsen, | 32 | 247 | 63 | 39 |
| ml/min, BS | | | | |
| OTR 23° C., 50% RH | >2000 | >2000 | >2000 | >2000 |
| WVTR 23° C., 50% RH | — | — | — | — |
| Moisture content | 5.43 | 7.64 | 7.6 | 5.71 |
| at 50% RH, % | | | | |

TABLE II
Precoated sheets

| Trial point | 1 | 2 | 3 | 4 |
|---|---|---|---|---|
| Coat weight, g/m² | 4 | 4 | 4 | 5 |
| Coating passages | 3 | 2 | 3 | 4 |
| Surface smoothness | 3.27 | 6.84 | 5.53 | 3.32 |
| PPS 1.0 MPa, μm | | | | |
| Air resistance Gurley, s | max | max | max | max |
| OTR 23° C., 50% RH (min) | 10.2 | >2000 | 1460 | 4.4 |
| OTR 23° C., 50% | 186 | >2000 | >2000 | 4.6 |
| RH (other cell) | | | | |
| WVTR 23° C., 50% RH (min) | 19.4 | — | — | 10.2 |
| WVTR 23° C., 50% | 21.2 | — | — | 11.7 |
| RH (other cell) | | | | |

TABLE III
Precoated and vacuum coated sheets (O.D.3.5)

| Trial point | 1 | 2 | 3 | 4 |
|---|---|---|---|---|
| OTR 23° C., 50% RH (min) | 1551 | >2000 | >2000 | 2 |
| OTR 23° C., 50% RH (other | >2000 | >2000 | >2000 | 4.6 |
| cell) | | | | |
| OTR 23° C., 80% RH (min) | — | — | — | 2.2 |
| OTR 23° C., 80% RH (other | — | — | — | 21 |
| cell) | | | | |
| WVTR 23° C., 50% RH (min) | 0.12 | — | 0.85 | 0.32 |
| WVTR 23° C., 50% RH (other | 0.14 | — | 1 | 1.1 |
| cell) | | | | |

TABLE IV
Precoated and vacuum coated sheets (O.D. 2.5)

| Trial point | 1 | 2 | 3 | 4 |
|---|---|---|---|---|
| OTR 23° C., 50% RH (min) | 309 | Not | Not | 3.6 |
| | | measured | measured | |
| OTR 23° C., 50% RH (other | >2000 | — | — | 52 |
| cell) | | | | |
| WVTR 23° C., 50% RH | 1.1 | — | — | 1.1 |
| WVTR 23° C., 50% RH (other | 1.7 | — | — | 1.5 |
| cell) | | | | |

Unless specified otherwise, the properties or parameters discussed in the present disclosure are determined according to the following standard methods:

| Property | Method used |
|---|---|
| Grammage | ISO 536: 2012 |
| Thickness single sheet | ISO 534: 2011 |
| Density single sheet | ISO 534: 2011 |
| Smoothness PPS 1 MPa, top side (TS) | ISO 8791-4: 2007 |
| and back side (BS) | |
| Roughness Bendtsen 0.1 MPa, top side (TS) | ISO 8791-2: 2013 |
| and back side (BS) | |
| Opacity | ISO 2471 |
| Tensile properties, machine direction | ISO 1924-3: 2005 |
| (MD) and cross direction (CD) | |
| Cobb Water Absorbency 60s, top side (TS) | ISO 535: 2014 |
| and back side (BS) | |
| Air resistance Gurley, L&W, side to be coated | ISO 5636-5: 2013 |
| Moisture content | Oven drying |
| Oxygen transmission rate (OTR) | ASTM F1927 - 98 |
| Water vapor transmission rate (WVTR) | ASTM F1249 - 90 |

OTR and WVTR were measured at 23° C. and 50% RH, with a few exceptions measured at 80% RH, as detailed in Tables I-IV. Instruments from Mocon were used. The side of the sample with the precoat layer and vacuum coating layer faced the oxygen or water vapor flow. Samples were measured in duplicate, simultaneously in the same apparatus.

1. A method for manufacturing a vacuum coated paper,
said method comprising:
a) providing a paper substrate, wherein said paper substrate comprises 0.3-60 kg/ton of a humectant, based on a total dry weight of the paper substrate,
b) applying a precoat layer to the paper substrate, and
c) applying a vacuum coating layer to the precoat layer to obtain a vacuum coated paper.

2. The method according to claim 1, wherein the paper substrate has a grammage in the range of 20-150 g/m².

3. The method according to claim 1, wherein the paper substrate further comprises a mineral filler in an amount of 1-30 wt %, based on the total dry weight of the paper substrate.

4. The method according to claim 1, wherein the paper substrate has a Gurley Hill value below 5000 s/100 ml, as measured according to standard ISO 5636-5.

5. The method according to claim 1, wherein the paper substrate has a water vapor transmission rate (WVTR), measured according to the standard ASTM F1249-90 at 50% relative humidity and 23° C., of above 200 g/m²/24 h.

6. The method according to claim 1, wherein the paper substrate is surface sized on one or two sides with a surface sizing composition.

7. (canceled)

8. The method according to claim 6, wherein a grammage of the surface sizing composition is 0.2-10 g/m², based on dry weight.

9. The method according to claim 1, wherein said paper substrate comprises 0.5-50 kg/ton, of the humectant, based on the total dry weight of the paper substrate.

10. The method according to claim 1, wherein the humectant is selected from a group consisting of: low molecular weight polyols, sugar alcohols, metal salts, and combinations thereof.

11. The method according to claim 1, wherein the humectant is comprises a sugar alcohol.

12. The method according to claim 1, wherein the humectant is a metal salt.

13. The method according to claim 1, wherein the humectant is present in bulk of the paper substrate, or at a surface of the paper substrate, or both.

14. (canceled)

15. The method according to claim 1, wherein the precoat layer comprises a polymer selected from a group consisting of: a polyvinyl alcohol (PVOH), a polyurethane, a polysaccharide, and combinations thereof.

16. The method according to claim 1, wherein the precoat layer comprises at least 50 wt % of a PVOH, based on a total dry weight of the precoat layer.

17. (canceled)

18. The method according to claim 1, wherein a grammage of the precoat layer is in a range of 1-20 g/m², based on dry weight.

19. The method according to claim 1, wherein the vacuum coating layer is applied to the precoat layer by physical vapor deposition (PVD) or chemical vapor deposition (CVD).

20. The method according to preceding claim 1, wherein the vacuum coating layer is an inorganic vacuum coated layer.

21. The method according to claim 1, wherein the vacuum coating layer comprises a metal or metal oxide selected from a group consisting of: aluminum, magnesium, silicon, copper, aluminum oxides, magnesium oxides, silicon oxides, and combinations thereof.

22. The method according to claim 1, wherein the vacuum coating layer is an organic vacuum coated layer.

23. (canceled)

24. The method according to claim 1, wherein the vacuum coating layer has a thickness in a range of 10-600 nm.

25. The method according to claim 1, wherein the vacuum coated paper has an oxygen transmission rate (OTR), measured according to the standard ASTM F1927-98 at 50% relative humidity and 23° C., of less than 10 cc/m²/24 h.

26. The method according to claim 1, wherein the vacuum coated paper has a water vapor transmission rate (WVTR), measured according to the standard ASTM F1249-90 at 50% relative humidity and 23° C., of less than 10 g/m²/24 h.

27. A vacuum coated paper comprising:
a paper substrate,
a precoat layer, and
a vacuum coating layer,
wherein the precoat layer is arranged between and in contact with the paper substrate and the vacuum coating layer, and
wherein said paper substrate comprises 0.3-60 kg/ton of a humectant, based on a total dry weight of the paper substrate.

28. (canceled)

29. (canceled)

30. (canceled)

31. (canceled)

32. (canceled)

33. (canceled)
